(19) United States
(12) Patent Application Publication
(10) Pub. No.: US 2003/0223182 A1
(43) Pub. Date: Dec. 4, 2003

(54) Information processing apparatus and window size control method used in the same unit

(75) Inventor: Takao Yurugi, Ome-shi (JP)

Correspondence Address: Finnegan, Henderson, Farabow, Garrett & Dunner, L.L.P., 1300 I Street, N.W., Washington, DC, 20005-3315, US

(73) Assignee: KABUSHIKI KAISHA TOSHIBA

(21) Appl. No.: 10/424,100

(22) Filed: Apr. 28, 2003

(30) Foreign Application Priority Data
May 29, 2002 (JP) 2002-155436

(51) Int. Cl. H05K 5/00

(52) U.S. Cl. 361/679

(57) ABSTRACT

An information processing apparatus allows a plurality of windows to be displayed on a display screen. The apparatus includes a unit which generates a button event in response to an operation of a given button, a unit which detects a current window size of an active window upon generation of the button event, and a unit which switches the detected current window size of the active window to a different window size.

### CROSS-REFERENCE TO RELATED APPLICATIONS

This application is based upon and claims the benefit of priority from the prior Japanese Patent Application No. 2002-155436, filed May 29, 2002, the entire contents of which are incorporated herein by reference.

### BACKGROUND OF THE INVENTION

1. Field of the Invention

The present invention relates to an information processing apparatus such as a personal computer and a window size control method used in the same apparatus. More specifically, the invention relates to an information processing apparatus that is capable of displaying a plurality of windows on a display screen and a window size control method used in the same apparatus.

2. Description of the Related Art

A multi-window system is generally adopted in an information processing apparatus such as a personal computer. The multi-window system is a window environment that is capable of displaying a plurality of windows, which correspond to various programs such as applications and utilities, on a display screen.

The multi-window system is usually provided with a graphical user interface for controlling each of the windows. As one graphical user interface, a menu and a button icon for resizing the window are arranged on each window. A user selects a command for resizing from the menu by using a mouse or clicks the button icon by using the mouse, to switch the size of the window to one of normal size, full screen size and minimum size.

A shortcut key function for switching the size of an active window through a keyboard is also known. Using the shortcut key function, a user can resize the active window immediately without performing an operation for selecting a command for resizing or an operation for clicking a button icon.

In the shortcut key function, however, a shortcut key is a combination of an auxiliary key including one or more keys such as “Ctrl” and “Alt” keys and another key such as an alphabetic key. It is thus necessary to depress a plurality of keys at once in order to use a shortcut key function.

Moreover, a combination of keys for a shortcut key function varies with a target window size. In other words, a target window size is explicitly designated by a combination of input keys for a shortcut key function. For this reason, a user cannot switch a window size to a desired one unless he or she remembers a plurality of combinations of keys corresponding to their respective window sizes (normal size, full screen size and minimum size).

It is thus desired to be able to achieve a mechanism for switching a window size through a simpler operation than using a shortcut key.

### BRIEF SUMMARY OF THE INVENTION

According to an embodiment of the present invention, there is provided an information processing apparatus that is capable of displaying a plurality of windows on a display screen, comprising means for generating a button event in response to an operation of a given button, means for detecting a current window size of an active window upon generation of the button event, and means for switching the current window size of the active window to a window size which differs from the detected current window size.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a front view showing an outward appearance of a computer according to an embodiment of the present invention;

FIG. 2 is a block diagram of a system configuration of the computer shown in FIG. 1;

FIG. 3 is a diagram showing an example of an arrangement of buttons provided on a remote control unit that allows communications with the computer of FIG. 1;

FIG. 4 is a diagram showing an example of the order in which a window size of the computer of FIG. 1 is switched;

FIG. 5 is a diagram showing another example of the order in which a window size of the computer of FIG. 1 is switched;

FIG. 6 is a block diagram showing an example of a process from when a button is depressed in the computer of FIG. 1 until when the window size thereof is switched;

FIG. 7 is a flowchart showing an example of a procedure of a window size switching process performed by window size switching programs used in the computer of FIG. 1;

FIG. 8 is a diagram of an active window whose window size is switched through the window size switching process shown in FIG. 7;

FIG. 9 is a block diagram showing another example of a process performed from when a button is depressed in the computer of FIG. 1 until when the window size thereof is switched;

FIG. 10 is a flowchart showing another example of the window size switching process performed by the window size switching programs used in the computer of FIG. 1;

FIG. 11 is a view showing an example of a window size selection screen used in the window size switching process of FIG. 7; and

FIG. 12 is a view showing another example of the window size selection screen used in the window size switching process of FIG. 7.

### DETAILED DESCRIPTION OF THE INVENTION

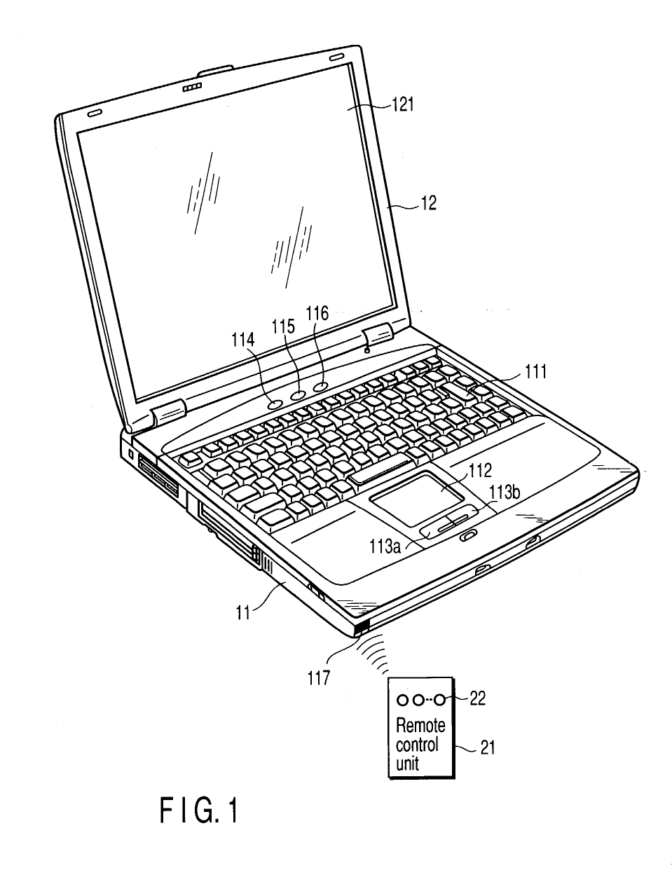

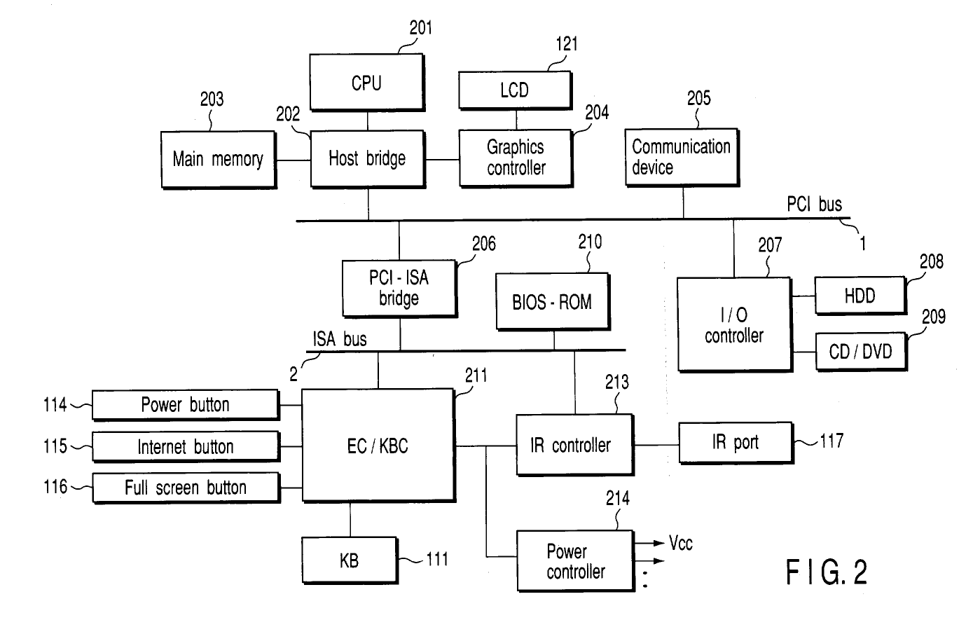

An embodiment of the present invention will now be described with reference to the accompanying drawings. Referring to FIGS. 1 and 2, a configuration of an information processing apparatus according to the embodiment will be described first. The information processing apparatus is implemented as a notebook type personal computer.

FIG. 1 is a front view of the present computer whose display unit is opened. The computer includes a computer body 11 and a display unit 12. The display unit 12 incorporates a display device 121 that is composed of an LCD (liquid crystal display). The display device 121 is located in substantially the central part of the display unit 12.

The display unit 12 is attached to the computer body 11 such that it can freely turn between an open position and a close position. The computer body 11 is shaped like a thin box-type housing. The computer body 11 has a keyboard 111, a touch pad 112 and right and left touch pad buttons 113a and 113b on its top.

The computer body 11 also has a power button 114 and two accessory buttons 115 and 116 on its rear top. The power button 114 is an externally input button that is formed of hardware and used as an operation button for turning on/off the computer. The two accessory buttons 115 and 116 are each an externally input button that is made of hardware. The accessory button 115 can be assigned an application program such as an Internet browser. When the accessory button 115 is depressed, the application program is started.

The accessory button 116 is assigned a function for switching a size of each of windows displayed on the display screen of the display device 121. Whenever the accessory button 116 is depressed once, the window size of the currently active window (active window) is automatically switched to a different window size.

More specifically, each window is displayed in one of normal size, full screen size and minimum size. Whenever the accessory button 116 is depressed once, the window size of the active window is switched to normal size, full screen size, minimum size, normal size, full screen size, . . . in the order designated.

Furthermore, whenever the accessory button 116 is depressed once, the window size of the active window can alternately be toggled between the normal size and full screen size.

Hereinafter, the accessory button 116 is referred to as a full screen button.

The computer body 11 also has a communication port 117 on its front to perform communications with an external remote control unit 21. The communication port 117 is a transmit/receive device that performs data communications with an external device by, e.g., infrared rays. Hereinafter, the communication port 117 is referred to as an IR port.

The remote control unit 21 is an external device that remotely controls the operation of the present computer. The remote control unit 21 has a plurality of remote control buttons on its top. The remote control buttons include a full screen button 22. Like the full screen button 116 on the computer body 11, the full screen button 22 serves as an operation button to switch the window size of the active window to a different window size.

More specifically, whenever the full screen button 22 is depressed once, the size of the active window is switched to normal size, full screen size, minimum size, normal size, full screen size, . . . in the order designated. Furthermore, whenever the full screen button 22 is depressed once, the size of the active window can alternately be toggled between normal size and full screen size.

A user can resize the active window by performing a simple operation of the full screen button 22 in a remote place from the computer using the remote control unit 21.

FIG. 2 shows a system configuration of the present personal computer. As shown in FIG. 2, the computer includes a CPU 201, a host bridge 202, a main memory 203, a graphics controller 204, a communication device 205, a PCI-ISA bridge 206, an I/O controller 207, a hard disk drive (HDD) 208, a CD/DVD drive 209, a BIOS-ROM 210, an embedded controller/keyboard controller IC (EC/KBC) 211, an infrared controller (IR controller) 213 and a power controller 214.

The CPU 201 is a processor provided to control the operation of the computer. The CPU 201 executes the operating system (OS) and application programs/utility programs which are loaded into the main memory 203 from the hard disk drive (HDD) 208. The CPU 201 also executes the BIOS (basic input output system) stored in the BIOS-ROM 210. The control of window size using the full screen button 22 or 116 is performed by a dedicated utility program.

The host bridge 202 is a bridge device that connects a local bus of the CPU 201 and a PCI bus 1 bidirectionally. The graphics controller 204 controls the LCD 121 serving as a display monitor of the present computer. The communication device 205 is one of PCI devices and used to communicate with a computer network such as the Internet. The I/O controller 207 is one of the PCI devices and includes an IDE (integrated drive electronics) controller which controls the hard disk drive (HDD) 208 and CD/DVD drive 209.

The PCI-ISA bridge 206 is a bridge device that connects the PCI bus 1 and ISA bus 2 bidirectionally and includes various system devices such as a system timer, a DMA controller and an interrupt controller. The BIOS-ROM 210 stores a BIOS. The BIOS is a program to control the hardware components in the system.

The BIOS includes a button event processing routine. The button event processing routine is to process a button event that occurs when a user depresses the full screen button 22 or 116.

The embedded controller/keyboard controller IC (EC/KBC) 211 is a one-chip microcomputer in which an embedded controller for controlling power and a keyboard controller for controlling the keyboard 111 are integrated.

The EC/KBC 211 has a function of powering on/powering off the computer in association with the power controller 214 in response to a user's depression of the power button 114. When a user depresses the full screen button 22 or 116, the EC/KBC 211 generates a button event that represents the depression. The CPU 201 is notified of the button event in response to a hardware interrupt signal issued from EC/KBC 211 and thus executes the button event processing routine of the BIOS.

The IR controller 213 is a communication device that performs data communications with an external device by infrared rays. When the IR controller 213 receives a signal from the remote control unit 21 via the IR port 117, the EC/KBC 211 generates the above button event.

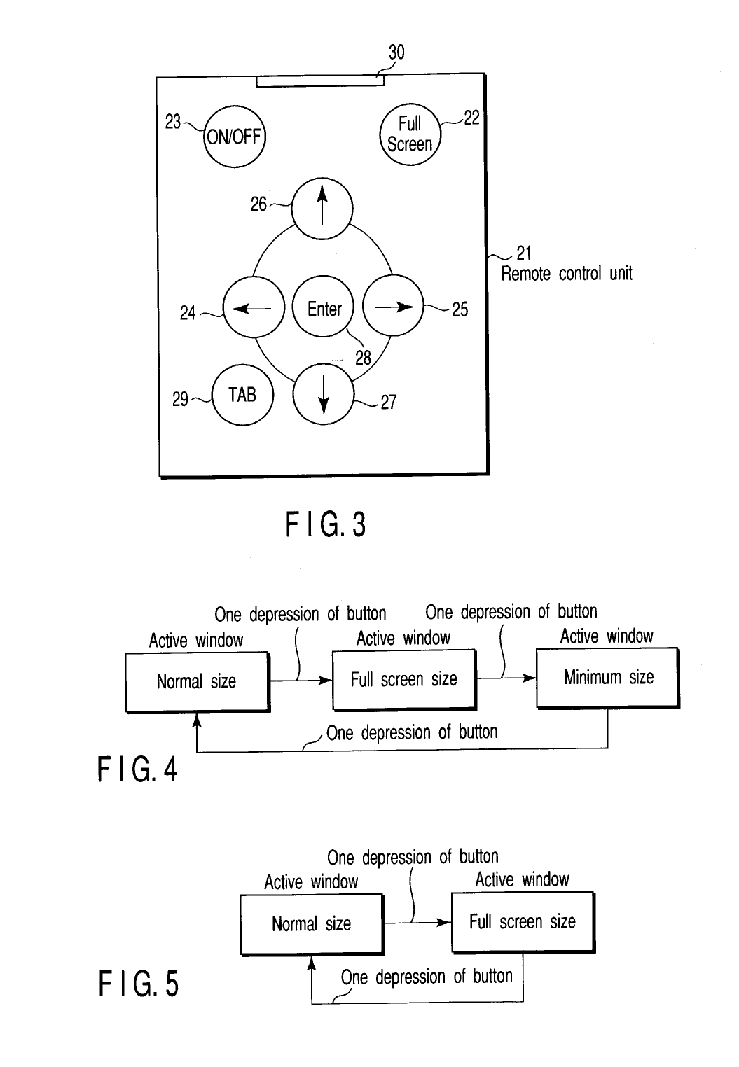

FIG. 3 shows an example of an arrangement of buttons on the remote control unit 21.

For example, the remote control unit 21 is shaped like a card-type thin housing and has, on its top, a power button 23, cursor buttons 24, 25, 26 and 27, an enter button 28 and a tab button 29, as shown in FIG. 3, in addition to the above-described full screen button 22. The remote control unit 21 also has an IR port 30 for infrared communications at one end.

The power button 23 is a button to designate the power-on/power-off of the computer. The cursor buttons 24, 25, 26 and 27 correspond to a plurality of cursor keys on the key board 111, i.e., “←,” “←,” “→,” and “↓” keys, respectively. The enter button 28 and tub button 29 correspond to the “Enter” key and “Tab” key, respectively.

Even though any button is depressed, the remote control unit 21 transmits a signal (remote control code) corresponding to the depressed button to the computer by infrared rays.

A window size switching process, which is performed by a depression of the full screen button 22 or 116, will now be described with reference to FIGS. 4 and 5.

FIG. 4 shows an example in which the size of the active window is switched to normal size, full screen size, minimum size, and normal size in the order designated whenever the full screen button 22 or 116 is depressed once.

The active window means a currently focused one of windows on the display screen or a window in which a cursor can be moved and to which a command and a text can be input.

If the full screen button 22 or 116 is depressed once when the active window is displayed in the normal size, the window size of the active window is switched from the normal size to the full screen size.

If the full screen button 22 or 116 is depressed once again, the window size of the active window is switched from the full screen size to the minimum size. If the full screen button 22 or 116 is depressed once again, the window size of the active window is switched from the minimum size to the normal size.

FIG. 5 shows an example in which the size of the active window is alternately switched between normal size and full screen size whenever the full screen button 22 or 116 is depressed once.

If the full screen button 22 or 116 is depressed once when the active window is displayed in the normal size, the window size of the active window is switched from the normal size to the full screen size. If the full screen button 22 or 116 is depressed once again, the window size of the active window is returned to the normal size.

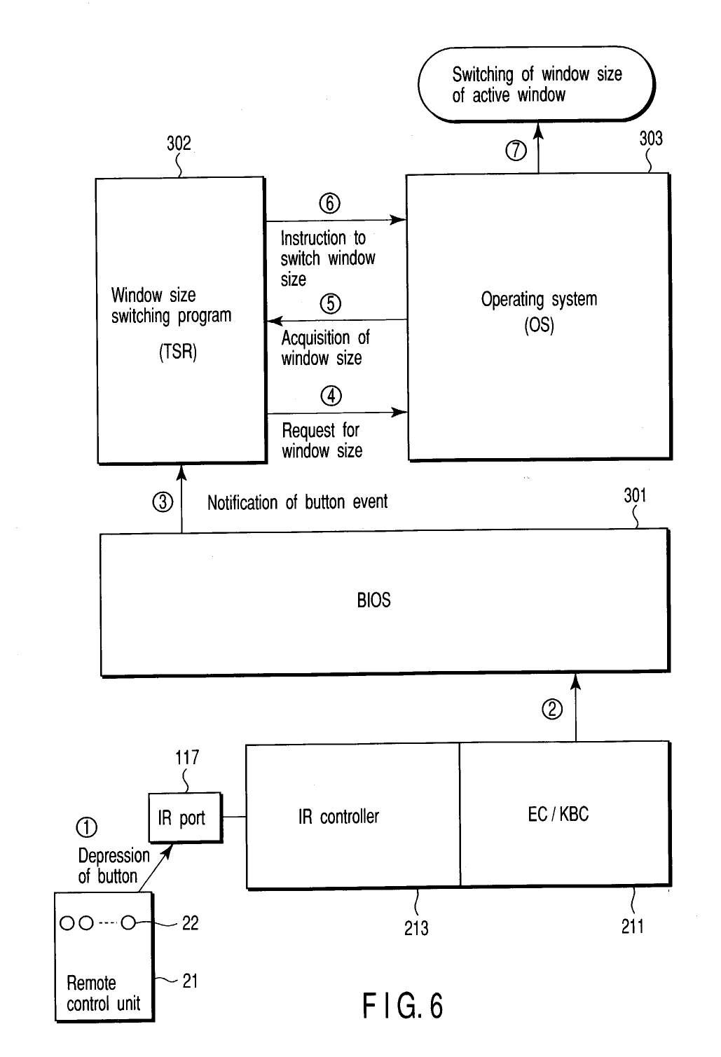

The principle of the window size switching process in the above embodiment will now be described with reference to FIG. 6.

The respective windows on the display screen are controlled by an operating system (OS) 303. The operating system 303 supports a multi-window environment and has a window size switching function using a shortcut key. In this function, the window size of the active window is resized to that designated by an input shortcut key. For example, there are three shortcut keys shown below to input a command for designating a window size.

(1) [Alt]+[Space]+[X]: shortcut keys that correspond to a command for designating a full screen size.

(2) [Alt]+[Space]+[N]: shortcut keys that correspond to a command for designating a minimum size.

(3) [Alt]+[Space]+[R]: shortcut keys that correspond to a command for returning the window size to the original size.

The operating system 303 includes an API (application programming interface) for using the window size switching function of the operating system 303 in the application programs.

In the present embodiment, the window size switching is realized by use of the API. In other words, the button event that indicates a depression of the full screen button 22 or 116 is emulated by a command (corresponding to a certain shortcut key) for causing the operating system 303 to execute a procedure for the window size switching process, and the command is transmitted to the operating system 303. This emulation is performed by a window size switching program 302.

The window size switching program 302 is a utility program exclusively for performing a window size switching process in response to the button event that indicates a depression of the full screen button 22 or 116. The program 302 is implemented as a TSR (terminate-and-stay-resident) program. During the operation of the operating system 303, the program 302 is always present on the main memory 203.

Hereinafter an operation from when the full screen button 22 on the remote control unit 21 is depressed until the window size is switched will be described.

(1): Depression of Button

When a user depresses the full screen button 22 on the remote control unit 21, the remote control unit 21 transmits a signal indicative of the depression of the full screen button 22 to the computer by infrared rays. This signal contains code data corresponding to the full screen button 22. The signal transmitted from the remote control unit 21 is sent to the IR controller 213 through the IR port 117.

(2) and (3): Generation of Button Event

When the IR controller 213 receives the signal, the EC/KBC 211 generates a button event indicative of the depression of the full screen button 22. The generation of the button event is informed to the CPU 201 by an interrupt signal issued from the EC/KBC 211.

The CPU 201 therefore executes the button event processing routine of the BIOS 301.

In the button event processing routine of the BIOS 301, a factor of generation of the button event from the EC/KBC 211 is checked. This checking is performed by a value of a status register in the EC/KBC 211. The status register stores code data corresponding to the depressed button. If the button event generation factor is due to the depression of the full screen button 22, the button event processing routine of the BIOS 301 notifies the window size-switching program 302 of the generation of the button event indicating that the full screen button 22 is depressed.

As described above, both a process of generating the button event indicating that the full screen button 22 is depressed and that of notifying the window size switching program 302 of the generation of the button event are performed through collaboration between the EC/KBC 211 and BIOS 301.

(4), (5) and (6): Detection and Switching of Window Size

The window size switching program 302 performs both a process of detecting the current window size of the active window and that of switching the current window size of the active window to a window size different from the detected current window size each time it receives notification of generation of a button event. In other words, upon receiving notification of generation of a button event, the window size switching program 302 first issues a command, which requires a current window size of the active window, to the operating system 303 and thus acquires the current window size of the active window from the operating system 303 ((4) and (5)). Therefore, the window size-switching program 302 can detect the current window size of the active window.

After that, the window size switching program 302 determines a different target window size based on the detected current window size. The target window size is determined by both the predetermined order in which the window size is switched and the detected current window size.

The window size switching program 302 transmits a message, which designates the determined target window size, to the operating system 303 and thus instructs the operating system 303 to switch the window size of the active window (6). Accordingly, the operating system 303 performs the window size switching process (7).

The message is used to cause the operating system 303 to perform the same window size switching function as that performed when a shortcut key for designating the determined target window size is input. The message is implemented using the foregoing API. The message includes parameter indicative of the determined target window size. The operating system 303 resizes the active window to the window size designated by the parameter included in the message from the window size switching program 302.

As described above, according to the present embodiment, both the process of detecting the current window size of the active window and that of switching the current window size to a different window size are performed each time the full screen button 116 or 22 is depressed. Since the window size of the active window can be switched to a different window size each time a user depresses the button 116 or 22, the user can easily switch the window size only by a single button without remembering a plurality of combinations of keys corresponding to their respective window sizes.

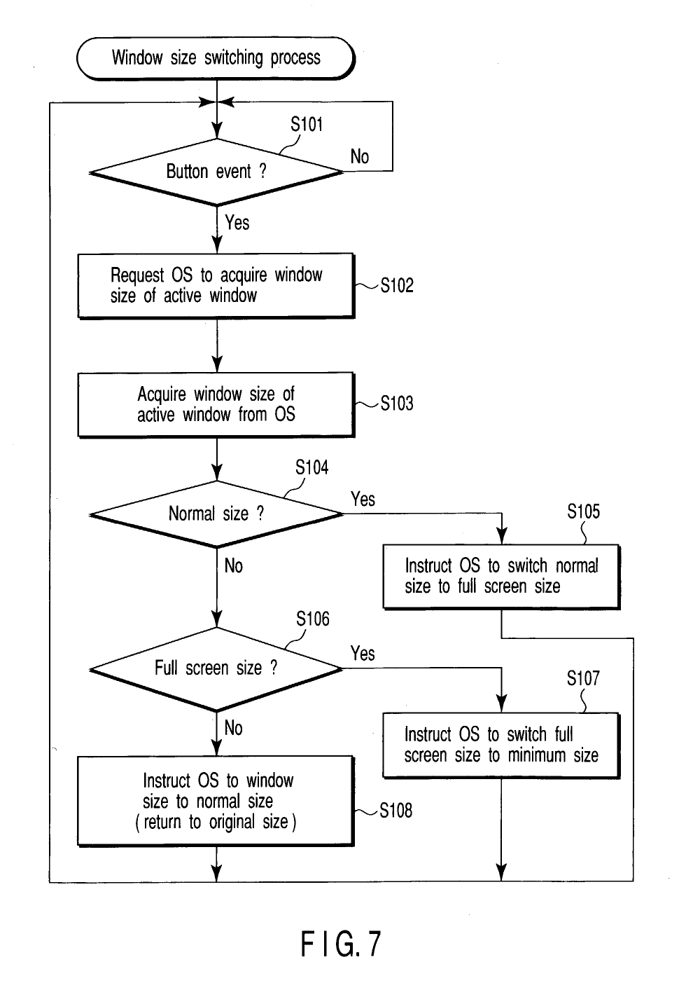

A procedure executed by the window size switching program 302 will now be described specifically with reference to the flowchart shown in FIG. 7. Assume here that the window size is switched to the normal size, full screen size and minimum size in the order designated.

The window size switching program 302 performs the following process each time it is notified that a button event is generated by depressing the full screen button 22 (YES in step S101).

The window size switching program 302 acquires the current window size of the active window from the operating system 303 (steps S102 and S103). Then, the program 302 determines whether the current window size is the normal size (step S104). If the current window size is the normal size (YES in step S104), the program 302 determines the full screen size as a target window size and instructs the operating system 303 to switch the current window size to the full screen size (step S105). In step S105, a message including the parameter indicating the full screen size is sent to the operating system 303. Thus, the window size of the active window is switched to the full screen size.

If the current window size of the active window is not the normal size, the window size switching program 302 determines whether the current window size is the full screen size or not (step S106). If the current window size is the full screen size (YES in step S106), the program 302 determines the minimum size as a target window size and instructs the operating system 303 to switch the current window size to the minimum size (step S107). In step S107, a message including the parameter indicating the minimum size is sent to the operating system 303. Thus, the window size of the active window is switched to the minimum size.

If the current window size is neither the normal size nor the full screen size or if the current window size is the minimum size (NO in step S106), the window size switching program 302 determines the normal size as a target window size and instructs the operating system 303 to switch the current window size of the active window to the normal size (step S108). In step S107, a message including the parameter indicating the normal size is sent to the operating system 303. Thus, the window size of the active window is switched to the normal size.

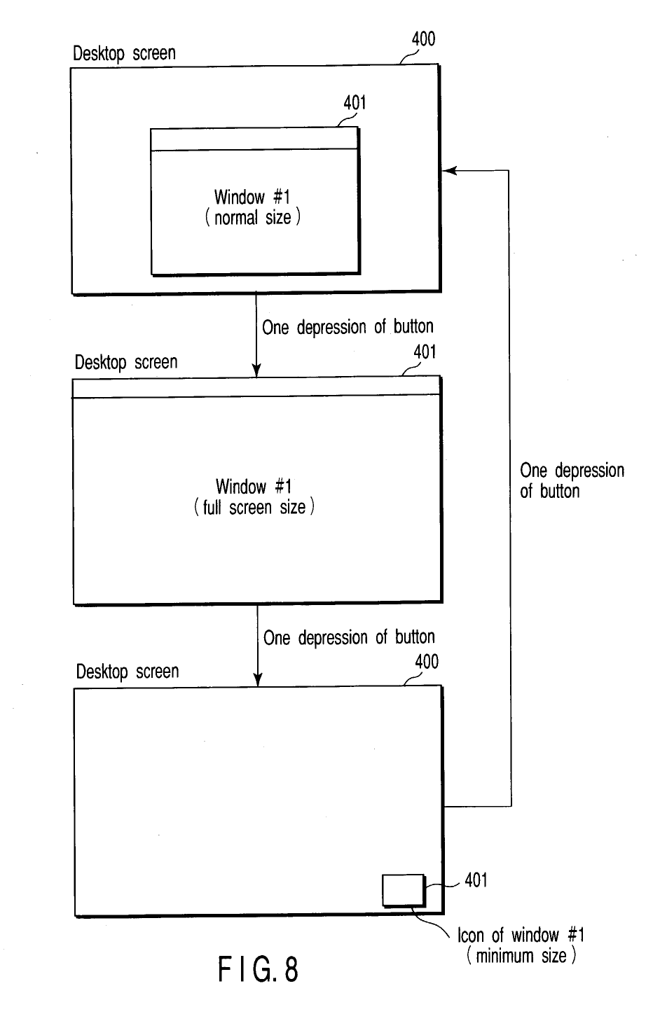

FIG. 8 shows the active window whose window size is switched.

A desktop screen 400 serves as an on-screen work area. The windows corresponding to respective programs are set on the desktop screen 400. An application window (#1) 401 is set on the desktop screen 400 and used as a currently focused active window.

The current window size of the application window (#1) 401 is the normal size. If the full screen button 22 is depressed once in this state, the window size of the application window (#1) 401 is switched to the full screen size. If the full screen button 22 is depressed once again, the window size of the application window (#1) 401 is switched to the minimum size.

If the system environment allows the application window (#1) 401 to continue serving as an active window even though the window size is switched to the minimum size, the window size of the application window (#1) 401 is switched to the normal size from the minimum size, when the full screen button 22 is depressed once again.

The window size need not be switched to the normal size, full screen size, minimum size and normal size in the order designated, but can be done in whatever order.

Instead of transmitting a message for explicitly designating the normal size as a target window size, a message indicating that the window size is returned to the original can be transmitted. This message is used to cause the operating system 303 to perform the same process as that performed when a shortcut key of (Alt+Space+R) is input.

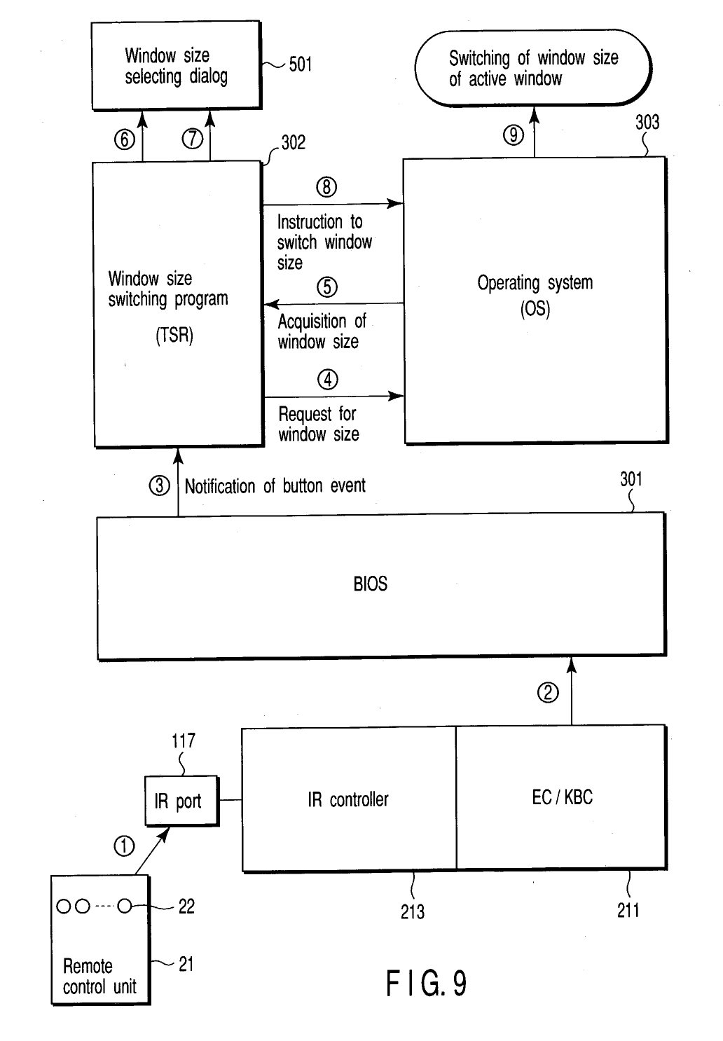

A second example of the window size switching process in the above embodiment will now be described with reference to FIGS. 9 to 12.

In the second example, when the full screen button 22 is depressed once, a window size selecting dialogue 501 is displayed on the display screen. The dialogue 501 is a window size selecting screen for selecting a target window size. A list of window sizes to be selected is displayed on the window size selecting dialogue 501. The target window size is switched from the currently selected window size to another window size whenever the full screen button 22 is depressed.

Prior to the description of the procedure for the window size switching process using the window size selecting dialogue 501, an example of the dialogue 501 will be described first.

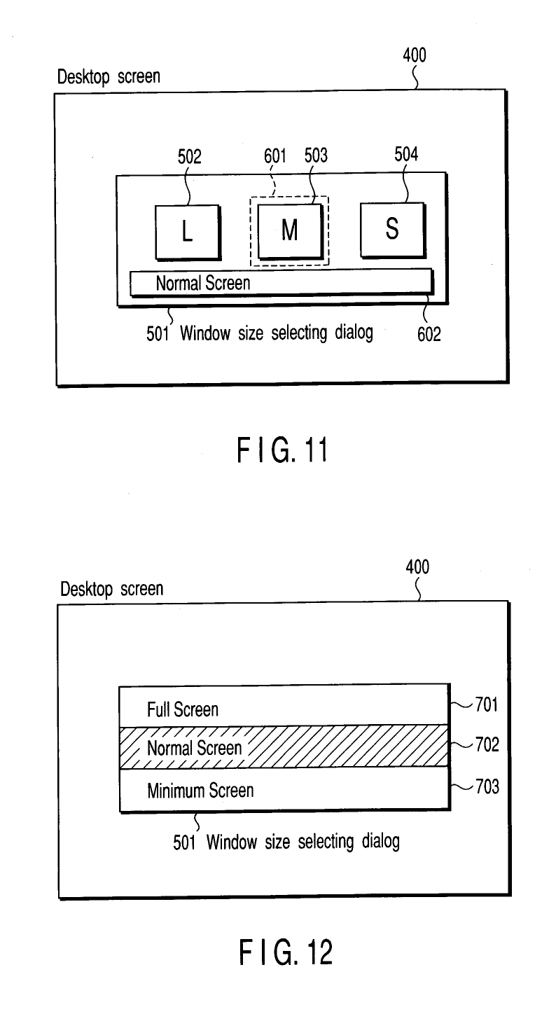

FIG. 11 shows a first example of the window size selecting dialogue 501. A window size list is displayed on the dialogue 501 and includes three icons 502, 503 and 504 corresponding to “full screen size,” “normal size,” and “minimum size”.

Letters “L,” “M” and “S” are put on the three icons 502, 503 and 504, respectively. A selection frame 601 is displayed on the icon corresponding to a window size that is currently selected as a target one. The selection frame 601 is identification information for identifying a window size that is currently selected as a target one. If the “normal size” is selected as a target window size, the selection frame 601 is displayed on the icon (M) 503. The display position of the selection frame 601 is moved to icon L, icon M, icon S, icon L, . . . in the order designated whenever the full screen button 22 is depressed once.

Furthermore, the window size selecting dialogue 501 includes a message display box 602. A message to show a window size corresponding to the icon currently selected by the selection frame 601 is displayed in the message display box 602.

FIG. 12 shows a second example of the window size selecting dialogue 501. The dialogue 501 includes three bars 701, 702 and 703 corresponding to “full screen size,” “normal size,” and “minimum size”, in place of the icons 502, 503 and 504. A message to show a window size corresponding to the bar is displayed on each of the bars. The message corresponding to the window size that is currently selected as a target one is highlighted. The highlight is moved to each of the bars whenever the full screen button 22 is depressed once.

The window size switching process using the window size selecting dialogue 501 will now be described with reference to FIG. 9.

Following is an operation from when the full screen button 22 on the remote control unit 21 is depressed until the window size switching process is performed.

(1) Depression of Button

When a user depresses the full screen button 22 on the remote control unit 21, the remote control unit 21 transmits a signal indicative of the depression to the computer by infrared rays. This signal contains code data corresponding to the full screen button 22. The signal transmitted from the remote control unit 21 is sent to the IR controller 213 through the IR port 117.

(2) and (3) Generation of Button Event

In response to the reception of a signal by the IR controller 213, the EC/KBC 211 generates a button event indicative of the depression of the full screen button 22. The BIOS 301 is notified of the generation of the button event in response to an interrupt signal to the CPU 201, thereby executing the button event processing routine of the BIOS 301.

In the button event processing routine of the BIOS 301, a factor of generation of the button event from the EC/KBC 211 is checked. This is performed by checking, for example, a value of a status register in the EC/KBC 21. The status register stores code data indicating the depressed button. If the button event generation factor is due to the depression of the full screen button 22, the window size switching program 302 is notified of the generation of the button event indicating that the full screen button 22 is depressed in the button event processing routine of the BIOS 301.

(4) and (5) Detection of Window Size

Upon receiving notification of generation of a button event, the window size switching program 302 first issues a command, which requires a current window size of the active window, to the operating system 303 and thus acquires the current window size from the operating system 303. The current window size of the active window is therefore detected. Then, the window size-switching program 302 determines a candidate for a target window size different from the current window size based on the detected current window size. The candidate is determined by both the predetermined order in which the window size is switched and the detected current window size.

(6) Display of Window Size Selecting Dialogue

The window size switching program 302 displays the window size selecting dialogue 501, as shown in FIG. 11, on the display screen. In this case, the selection frame 601 is put on one of the three icons 502, 503 and 504, which corresponds to the window size currently selected as a candidate for a target window size.

(7) Change of Candidate for Target Window Size

The window size switching program 302 stands by for a specific period of time (e.g., two seconds) after the window size selecting dialogue 501 is displayed and monitors whether a new button event is generated within the time period. If a user depresses the full screen button 22 again, the window size switching program 302 is notified of the generation of the button event by the above-described processes (1) to (3). In this case, the window size switching program 302 moves the selection frame 601 displayed on the window size selecting dialogue 501 one time. In other words, the window size of a target candidate is changed.

(8) Change of Window Size

If a specific time (e.g., two seconds) elapses after the selection frame 601 is moved, the window size switching program 302 determines a window size corresponding to the icon on which the selection frame 601 is currently put as a target window size. Then, the program 302 transmits a message, which indicates the switching to the determined target window size, to the operating system 303 and causes the system 303 to perform the window size switching process. This message is used to cause the operating system 303 to perform the same window size switching process as that performed when a shortcut key for designating the determined target window size is input. The operating system 303 switches the window size of the active window to the target window size designated by the message (9).

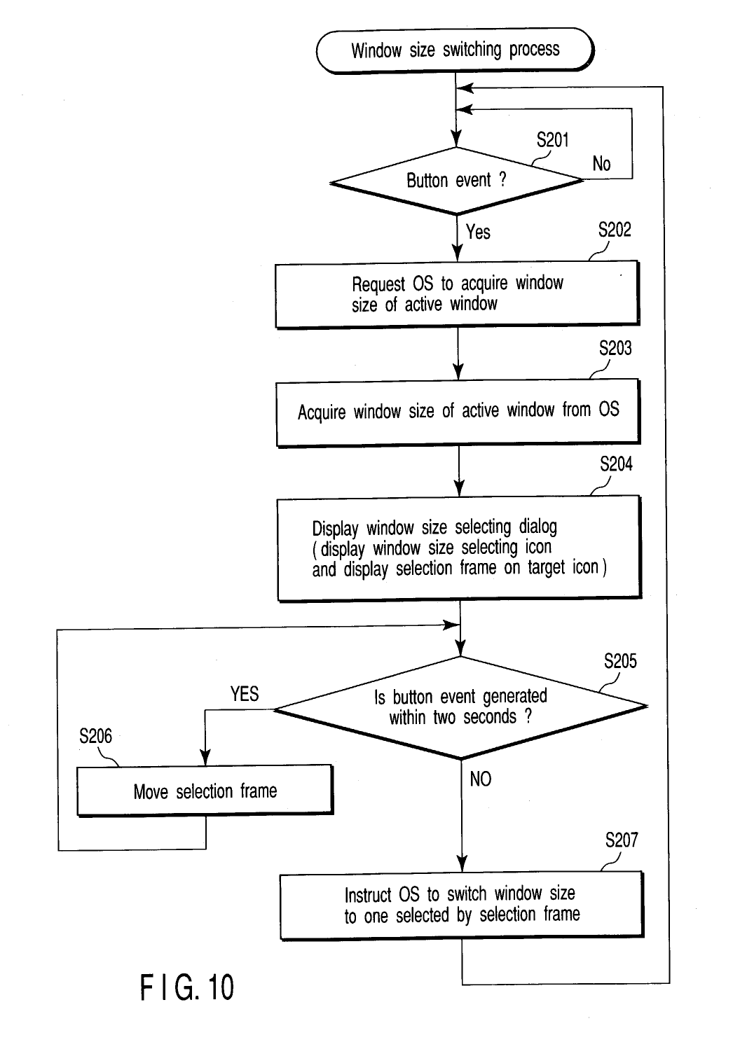

A procedure executed by the window size switching program 302 will now be described specifically with reference to the flowchart shown in FIG. 10.

The window size switching program 302 performs the following process when notification of generation of a button event is issued by depressing the full screen button 22 with no display of the window size selecting dialog 501 (YES in step S201).

The window size switching program 302 acquires the current window size of the active window from the operating system 303 (steps S202 and S203). Then, the program 302 determines a candidate for a target window size and displays the window size selecting dialog 501 (step S204). The selection frame 601 is put on the icon corresponding to the window size that is currently selected as the target candidate.

If a button event is generated again within two seconds of step S204 (YES in step S205), the window size switching program 302 moves the selection frame 601, which is displayed on the window size selecting dialog 501, one time to change the target candidate (step S206). Then, the program 302 returns to step S205 and monitors whether a button even is generated or not for two seconds. If no button event is generated within two seconds (NO in step S205), the program 302 determines a window size corresponding to the icon selected by the selection frame 601 as a target one and instructs the operating system 303 to switch the window size of the active window to the determined target window size (step S207). At this point in time, the window size selecting dialog 501 disappears from the display screen.

In step S207, the operating system 303 receives a message including parameter indicative of a target window size. Thus, the window size of the active window is switched to a window size corresponding to the icon selected by the selection frame 601.

The foregoing embodiment has been described with a particular emphasis on the case where the full screen button 22 on the remote control unit 21 is depressed. The same process is performed even when the full screen button 116 on the computer body 11 is depressed. The means for communications between the remote control unit 21 and the computer is not limited to infrared rays, but the communications can be performed using a radio signal (RF) or the like. Furthermore, the remote control unit 21 and the computer can be connected by wire.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An information processing apparatus that is capable of displaying a plurality of windows on a display screen, comprising:
means for generating a button event in response to an operation of a given button;
means for detecting a current window size of an active window upon generation of the button event; and
means for switching the current window size of the active window to a window size which differs from the detected current window size.

2. The information processing apparatus according to claim 1, further comprising:
a remote control unit on which the given button is provided; and
a receiver which receives a signal from the remote control unit, the signal being transmitted from the remote control unit in response to an operation of the given button, and
wherein the button event generating means includes means for generating the button event when the receiver receives the signal from the remote control unit.

3. The information processing apparatus according to claim 1, wherein the window size detecting means includes means for acquiring the current window size of the active window from an operating system, which controls each of the windows displayed on the display screen.

4. The information processing apparatus according to claim 1, wherein each of the windows displayed on the display screen has one of at least two window sizes of a normal size and a full screen size, and the window size switching means includes means for when the detected current window size of the active window is one of the normal size and the full screen size, switching the current window size to other of the two window sizes of the normal size and the full screen size.

5. The information processing apparatus according to claim 1, wherein each of the windows displayed on the display screen is controlled by an operating system, the operating system having a window size switching function of setting a window size of the active window to a window size, which is designated by a shortcut key including a combination of two or more specific keys, and the window size switching means includes means for determining a target window size based on the detected current window size of the active window and means for transmitting, to the operating system, a message to cause the operating system to perform a window size switching function which is same as that of setting the window size by the shortcut key for designating the determined target window size.

6. The information processing apparatus according to claim 1, wherein the window size switching means includes means for displaying a window size selection screen, which indicates a list of a plurality of window sizes to which the active window is set, on the display screen in response to the generation of the button event and means for switching a window size, which is currently selected as a target window size from the list of window sizes displayed on the window size selection screen, to a different window size, when the button event is newly generated.

7. An information processing apparatus that is capable of displaying a plurality of windows on a display device, comprising:
a receiver which receives a signal from a remote control unit, the signal being transmitted from the remote control unit in response to an operation of a given button provided on the remote control unit;
means for generating a button event, which indicates that the given button is operated, when the receiver receives the signal from the remote control unit;
means for detecting a current window size of an active window in response to generation of the button event;
means for determining one of a plurality of window sizes, to which the active window is set and which differs from the detected current window size, as a target window size; and
means for switching the current window size of the active window to the determined target window size.

8. The information processing apparatus according to claim 7, wherein the window size detecting means includes means for acquiring the current window size of the active window from an operating system, which controls each of the windows displayed on the display device, in response to the generation of the button event.

9. The information processing apparatus according to claim 7, wherein each of the windows displayed on the display device is controlled by an operating system, the operating system having a window size switching function of setting a window size of the active window to a window size, which is designated by a shortcut key including a combination of two or more specific keys, in response to an operation of the shortcut key, and the window size switching means includes means for transmitting, to the operating system, a message to cause the operating system to perform a window size switching function which is same as that of setting the window size by the shortcut key for designating the determined target window size.

10. A method of controlling a window size of each of windows displayed on a display screen of an information processing apparatus, the method comprising:
generating a button event in response to an operation of a given button;
detecting a current window size of an active window upon generation of the button event; and
switching the current window size of the active window to a window size which differs from the detected current window size.

11. The method according to claim 10, wherein the button event generating includes receiving a signal from a remote control unit on which the given button is provided and generating the button event when the signal is received.

12. The method according to claim 10, wherein the window size detecting includes acquiring the current window size of the active window from an operating system, which controls each of the windows displayed on the display screen.

13. The method according to claim 10, wherein each of the windows displayed on the display screen has one of at least two window sizes of a normal size and a full screen size, and the window size switching includes switching the current window size of the active window to one of the two window sizes of the normal size and the full screen size when the detected current window size is other of the normal size and the full screen size.

14. The method according to claim 10, wherein each of the windows displayed on the display screen is controlled by an operating system, the operating system having a window size switching function of setting a window size of the active window to a window size, which is designated by a shortcut key including a combination of two or more specific keys, in response to an operation of the shortcut key, and the window size switching includes determining a target window size based on the detected current window size of the active window and transmitting, to the operating system, a message to cause the operating system to perform a window size switching function which is same as that of setting the window size by the shortcut key for designating the determined target window size.

15. The method according to claim 10, wherein the window size switching includes displaying a window size selection screen, which indicates a list of a plurality of window sizes to which the active window is set, on the display screen in response to the generation of the button event and switching a window size, which is currently selected as a target window size from the list of window sizes displayed on the window size selection screen, to another window size, when the button event is newly generated.

16. A method of controlling a window size of each of windows displayed on a display screen of an information processing apparatus, the method comprising:
receiving a signal from a remote control unit, the signal being transmitted from the remote control unit in response to an operation of a given button provided on the remote control unit;
generating a button event, which indicates that the given button is operated, upon receipt of the signal from the remote control unit;
detecting a current window size of an active window in response to generation of the button event;
determining one of a plurality of windows, to which the active window is set and which differs from the detected current window size, as a target window size; and
switching the current window size of the active window to the determined target window size.

17. The method according to claim 16, wherein the window size detecting includes acquiring the current window size of the active window from an operating system, which controls each of the windows displayed on the display screen, in response to the generation of the button event.

18. The method according to claim 16, wherein each of the windows displayed on the display screen is controlled by an operating system, the operating system having a window size switching function of setting a window size of the active window to a window size, which is designated by a shortcut key including a combination of two or more specific keys, in response to an operation of the shortcut key, and the window size switching includes transmitting, to the operating system, a message to cause the operating system to perform a window size switching function which is same as that of setting the window size by the shortcut key for designating the determined window size.
